(19) United States
(12) Patent Application Publication
(10) Pub. No.: US 2018/0102372 A1
(43) Pub. Date: Apr. 12, 2018

(54) FERROELECTRIC COMPOSITION ON SEMICONDUCTOR AND METHOD FOR PRODUCING SAME

(71) Applicant: Board of Regents, The University of Texas System, Austin, TX (US)

(72) Inventors: Joseph Ho Yeen Ngai, Mansfield, TX (US); Reza M. Moghadam, Arlington, TX (US); Kamyar Ahmadi-Majlan, Arlington, TX (US)

(73) Assignee: Board of Regents, The University of Texas System, Austin, TX (US)

(21) Appl. No.: 15/730,706

(22) Filed: Oct. 11, 2017

Related U.S. Application Data
(60) Provisional application No. 62/406,915, filed on Oct. 11, 2016.

(51) Int. Cl. H01L 27/11502; H01L 29/51; H01L 49/02; H01L 21/28

(52) U.S. Cl. CPC H01L 27/11502; H01L 29/516; H01L 21/28291; H01L 28/55; H01L 28/75

(57) ABSTRACT

Techniques for fabricating ferroelectric materials and semiconductor devices using the materials. Material compositions including strontium, zirconium, titanium, and oxygen are disposed on a substrate material to produce ferroelectric devices.

### CROSS-REFERENCE TO RELATED APPLICATIONS

This application claims the benefit of U.S. Provisional Patent Application No. 62/406,915, entitled “Ferroelectric Composition on Semiconductor and Method for Producing Same,” which was filed on Oct. 11, 2016 and is herein incorporated by reference in its entirety.

### STATEMENT REGARDING FEDERALLY SPONSORED RESEARCH

This invention was made with government support by the National Science Foundation (NSF DMR-1508530). The government has certain rights in the invention.

### TECHNICAL FIELD OF THE INVENTION

This disclosure relates generally to techniques for fabricating a ferroelectric material, and more particularly to techniques for producing ferroelectric semiconductor devices using a fabricated ferroelectric material.

### BACKGROUND

Ferroelectric materials are used in the production of electrical components such as semiconductor devices. Relaxor ferroelectrics are a class of ferroelectrics that are characterized by an electric polarization that can be induced by an externally applied electric field. The polarization remains after the external electric field is removed; furthermore, the direction of the polarization can be reversed by the application of an external electric field in the opposite direction. Relaxors are a class of ferroelectrics that can be described by an ensemble of weakly interacting polar clusters, or Polar Nano-Regions (PNRs). In some relaxor systems, a ferroelectric state defined by the spontaneous emergence of long-range polarization at a temperature T_{C} occurs. In so-called canonical relaxors, though, spontaneous long-range polarization is not observed, and the PNRs enter a glass-like (termed non-ergodic) regime. A ferroelectric state can be achieved in some canonical relaxors even from within the non-ergodic regime through application of a sufficiently strong electric field. Yet, even in the absence of a ferroelectric state, applied-fields can re-orient PNRs to induce polarized states that persist for long periods of time. Such polarized states could offer non-volatile and hysteretic functionality in field-effect devices for applications.

The electronics industry, and particularly the field of computer circuitry, continues to experience a demand for improved components offering lower power consumption and greater miniaturization. Reducing power consumption in logic devices, or integrating both logic and memory functionalities into a single device are two pathways to potentially achieve these goals. Thus, a need remains for improved techniques for fabricating ferroelectric materials on semiconductors that meet requirements for scalability and electrical coupling.

### SUMMARY

According to a first aspect of the invention, there is provided a ferroelectric semiconductor device, including (1) a semiconductor substrate; (2) a ferroelectric material formed over the substrate; and wherein the ferroelectric material comprises a composition of the elements strontium (Sr), zirconium (Zr), titanium (Ti), and oxygen (O). The ferroelectric material composition includes SrZr_{0.7}Ti_{0.3}O₃.

Other aspects of the embodiments described herein will become apparent from the following description and the accompanying drawings, illustrating the principles of the embodiments by way of example only.

### BRIEF DESCRIPTION OF THE DRAWINGS

The following figures form part of the present specification and are included to further demonstrate certain aspects of the present claimed subject matter, and should not be used to limit or define the present claimed subject matter. The present claimed subject matter may be better understood by reference to one or more of these drawings in combination with the description of embodiments presented herein. Consequently, a more complete understanding of the present embodiments and further features and advantages thereof may be acquired by referring to the following description taken in conjunction with the accompanying drawings, in which like reference numerals may identify like elements, wherein:

FIG. 1 is an X-ray diffraction plot of ferroelectric compositions produced according to embodiments of the invention;

FIG. 2 is a cross-sectional electron microscope image of a ferroelectric composition produced according to an embodiment of the invention;

FIG. 3 depicts a direct space map of a ferroelectric material deposited on a substrate according to an embodiment of the invention;

FIG. 4 depicts a schematic of a ferroelectric material deposited on a substrate according to an embodiment of the invention;

FIG. 5 depicts a schematic of a ferroelectric material in a piezo-force microscopy testing configuration according to an embodiment of the invention;

FIGS. 5A-5C depict surface images of a ferroelectric material in a piezo-force microscopy testing configuration according to an embodiment of the invention;

FIG. 6 depicts a schematic of a metal-oxide semiconductor capacitor according to an embodiment of the invention;

FIG. 7 depicts a capacitance-voltage curve plot for the capacitor of FIG. 6;

FIG. 8 depicts a schematic of a field-effect transistor according to an embodiment of the invention;

FIG. 9A depicts a schematic of a gate stack of ferroelectric material according to an embodiment of the invention;

FIG. 9B is an equation of the current passing through the ferroelectric material stack of FIG. 9A;

FIG. 10 depicts a graph of a PUND measurement technique applied to the ferroelectric material stack of FIG. 9A;

FIG. 11A depicts a normalized current measurement plot of the data of FIG. 10;

FIG. 11B depicts another normalized current measurement plot of the data of FIG. 10;

FIG. 12A depicts a current-voltage plot of the data of FIG. 10;

FIG. 12B depicts a polarization-voltage plot of the data of FIG. 10;

FIG. 13 depicts a capacitance-temperature plot for a ferroelectric material according to an embodiment of the invention; and

FIG. 14 is a flow chart illustrating a method for fabricating a ferroelectric semiconductor device according to an embodiment of the invention.

### NOTATION AND NOMENCLATURE

Certain terms are used throughout the following description and claims to refer to particular system components and configurations. As one skilled in the art will appreciate, the same component may be referred to by different names. This document does not intend to distinguish between components that differ in name but not function. In the following discussion and in the claims, the terms “including” and “comprising” are used in an open-ended fashion, and thus should be interpreted to mean “including, but not limited to . . . .”

### DETAILED DESCRIPTION

The foregoing description of the figures is provided for the convenience of the reader. It should be understood, however, that the embodiments are not limited to the precise arrangements and configurations shown in the figures. Also, the figures are not necessarily drawn to scale, and certain features may be shown exaggerated in scale or in generalized or schematic form, in the interest of clarity and conciseness. The same or similar parts may be marked with the same or similar reference numerals.

While various embodiments are described herein, it should be appreciated that the present invention encompasses many inventive concepts that may be embodied in a wide variety of contexts. The following detailed description of exemplary embodiments, read in conjunction with the accompanying drawings, is merely illustrative and is not to be taken as limiting the scope of the invention, as it would be impossible or impractical to include all of the possible embodiments and contexts of the invention in this disclosure. Upon reading this disclosure, many alternative embodiments of the present invention will be apparent to persons of ordinary skill in the art. The scope of the invention is defined by the appended claims and equivalents thereof.

Illustrative embodiments of the invention are described below. In the interest of clarity, not all features of an actual implementation are described in this specification. In the development of any such actual embodiment, numerous implementation-specific decisions may need to be made to achieve the design-specific goals, which may vary from one implementation to another. It will be appreciated that such a development effort, while possibly complex and time-consuming, would nevertheless be a routine undertaking for persons of ordinary skill in the art having the benefit of this disclosure.

Ferroelectric materials can be deposited on substrates by various deposition techniques. However, conventional approaches to integrating and electrically coupling ferroelectric materials to semiconductors requires very thick ferroelectric materials to be grown, and or results in poor electrical coupling between the ferroelectric and semiconductor at the interface. The former prevents scaling of the device and the latter inhibits device performance.

Generally, the present invention provides a new ferroelectric material and techniques for producing electronic devices using the material. Embodiments of the invention entail a composition of elements comprising strontium (Sr), zirconium (Zr), titanium (Ti), and oxygen (O). This material compound is hereinafter referred to as “SZTO.” SZTO compound materials have been studied by others, focusing on the bulk properties (i.e., polycrystalline, large single-crystal samples) of such compositions. The prior studies of these materials did not find any ferroelectric properties in SZTO compositions, concluding that such compositions behave as normal dielectric materials.

In contrast to bulk SZTO compositions, the present invention entails the growth or deposition of films of a SZTO material. Embodiments entail single-crystalline (i.e., ordered vs. randomly oriented atoms) thin-film distribution of a SZTO composition. In some embodiments, the SZTO films are grown on a p-type germanium (Ge) substrate using molecular beam epitaxy (MBE) generation, in other embodiments, growth on other semiconducting substrates is possible. One applied MBE technique entailed the vaporization of the individual elements (Sr, Zr, Ti) in separate effusion cells and the combination of the vaporized elements via deposition onto a substrate without a buffer layer.

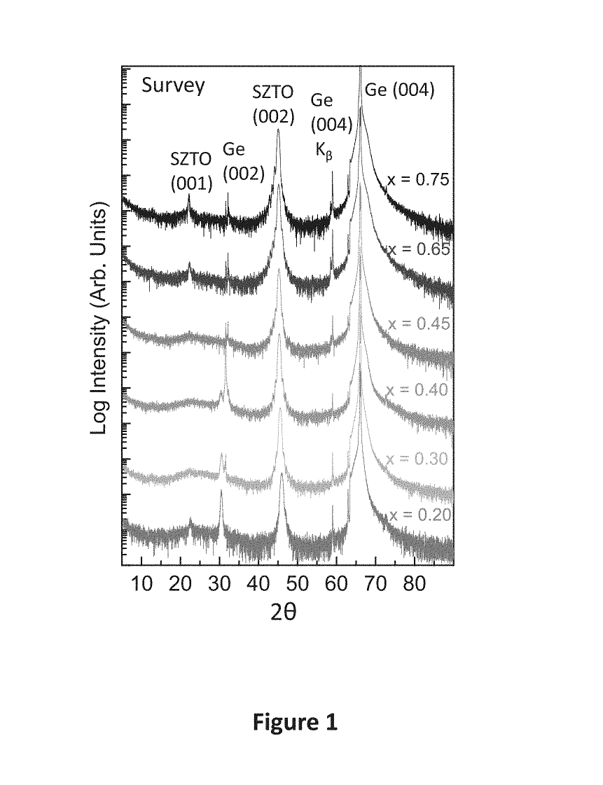

FIG. 1 shows an X-ray diffraction plot of various thin-film compositions of SZTO grown on a germanium substrate in accordance with some embodiments of the invention. The individual graphs represent SZTO compounds with different zirconium content. The zirconium content for each film compound is shown on the right-hand side of each graph, denoted by the “x” (e.g., the zirconium content for the compound represented in the bottom graph of FIG. 1 is 0.20). It will be appreciated by those skilled in the art that the individual element quantities disclosed herein are expressed in terms of the relative stoichiometric ratios of the respective elements in the compound.

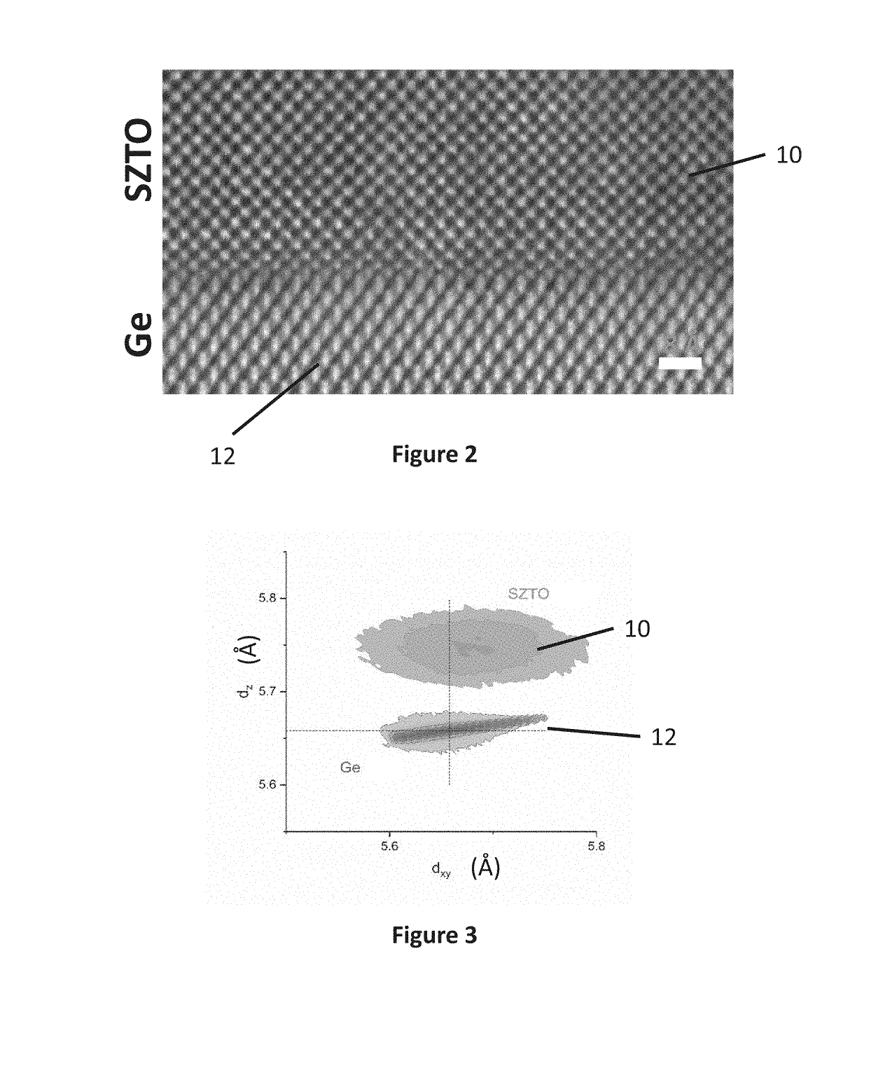

FIG. 2 shows a cross-sectional electron microscope image of a SZTO 10 material embodiment grown on a germanium substrate 12. The image shows the interface between the germanium substrate 12 and the SZTO 10 film layers. As shown in the image, the SZTO film layers are formed with a single crystal or monocrystalline distribution. Turning to FIG. 3, additional X-ray data is shown. FIG. 3 depicts a direct space map of the SZTO 10 material disposed on the germanium substrate 12. This mapping allows one to analyze the lattice constant (i.e., the physical dimension of the unit cells in the crystal lattice) of the SZTO 10 and the germanium 12. Analysis of the space map illustrated in FIG. 3 shows that the SZTO 10 material is partially strained (i.e., the atoms of the SZTO material are stressed beyond their normal interatomic distance) to the germanium 12.

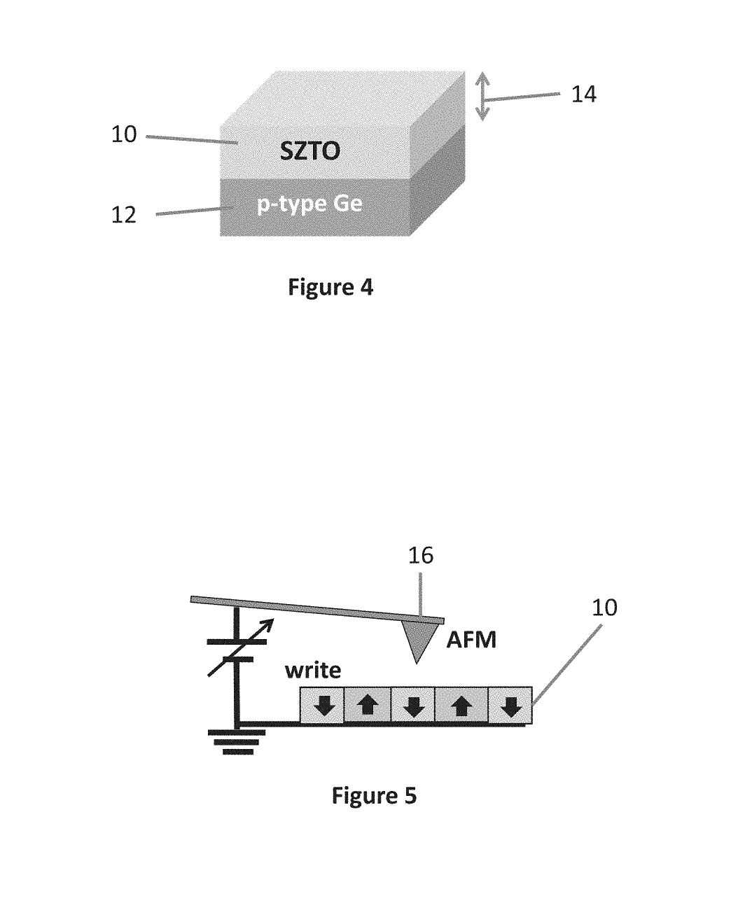

Various tests were performed on the fabricated SZTO 10 material to verify its relaxor ferroelectric characteristics. FIG. 4 illustrates an embodiment of the SZTO 10 material grown on a p-type germanium substrate 12. In some embodiments, the SZTO 10 composition comprises SrZr_{0.7}Ti_{0.3}O₃. Testing was performed on embodiments with the SZTO 10 composition epitaxially grown on the substrate 12 with a film thickness 14 ranging between five to fifteen nanometers. It will be appreciated that other embodiments of the invention may be implemented with the SZTO 10 material formed at different thicknesses and in various geometric configurations (e.g., in disc, square, or other shapes).

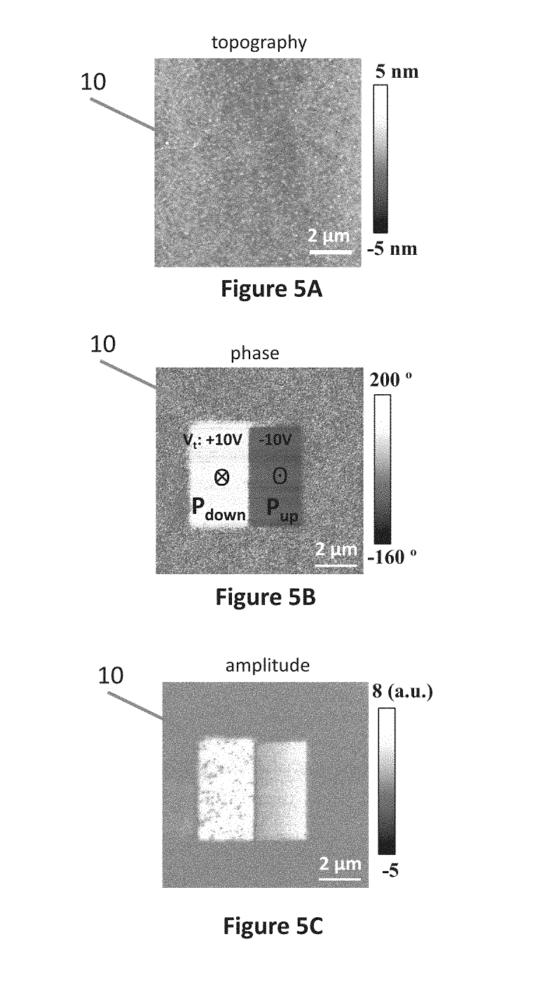

Testing of the SZTO 10 material embodiments included piezo-force microscopy (PFM) analysis. An atomic force microscope was used to image the topography of the SZTO 10 material surface at the nanometer scale. FIG. 5 illustrates a PFM testing configuration, wherein a potential bias (e.g., voltage +10V −10V) is applied to the cantilever 16 tip of the AFM and rastered across specific locations of the SZTO 10 surface. The PFM measurements showed that robust “up” and “down” polarization domains (depicted as up and down arrows in FIG. 5) can be written on the SZTO 10 material. By application of a localized voltage of opposite polarity via the cantilever 16 tip, individual domain polarizations on the SZTO 10 material were selectively switched between up-down polarization. The triggering or coercive voltage (applied in the opposite polarity) required to switch the polarized dipole domains was found to be approximately 2V for some tested embodiments. It will be appreciated by those skilled in the art that the application of a biasing potential to set a domain on the SZTO 10 material in one direction or the other can be implemented by various known means and configurations. The “written” domain polarizations remained stable on the SZTO 10 film material long after the biasing voltage (created electric field) was removed. This characteristic of the fabricated ferroelectric SZTO 10 material allows for the implementation of embodiments as memory cell devices.

FIGS. 5A-5C depict surface images of the SZTO 10 material during the PFM analysis described above. As shown in FIG. 5A, the particular SZTO 10 material embodiment provides a smooth surface, with a film having less than 0.44 nm in roughness. FIG. 5B depicts the SZTO 10 material with different polarization domains. By application of a potential bias with different polarities via the cantilever 16 tip, an ‘up’ polarization was written next to a ‘down’ polarization on the SZTO 10 film. FIG. 5B and FIG. 5C shows the SZTO 10 material surface with different polarization regions that can be distinguished in the PFM signal in both phase and amplitude. The phase difference arises from the change in the sign of the surface polarization charges (e.g. positive vs. negative) between two different polarization states. A corresponding change in the amplitude of the PFM signal response is also detected between the two different polarization states (FIG. 5C).

The fabricated SZTO 10 material can be integrated to produce a field-effect transistor (FET). As understood by those skilled in the art, the basis of an FET is a metal-oxide semiconductor (MOS) capacitor. FETs, in which the conventional gate oxide is replaced with a ferroelectric material, could significantly reduce the power necessary to operate the transistor, and also introduce memory functionality into the device. Reduced power consumption in ferroelectric field-effect devices can be achieved by exploiting the negative capacitance of the ferroelectric gate. Memory functionality can be achieved by exploiting the remnant, re-orientable, polarization of the ferroelectric gate to maintain the transistor's state in the absence of an applied electric field (i.e. power). The key to realizing such ferroelectric field-effect devices is integrating and electrically coupling ferroelectric materials on and to semiconducting materials.

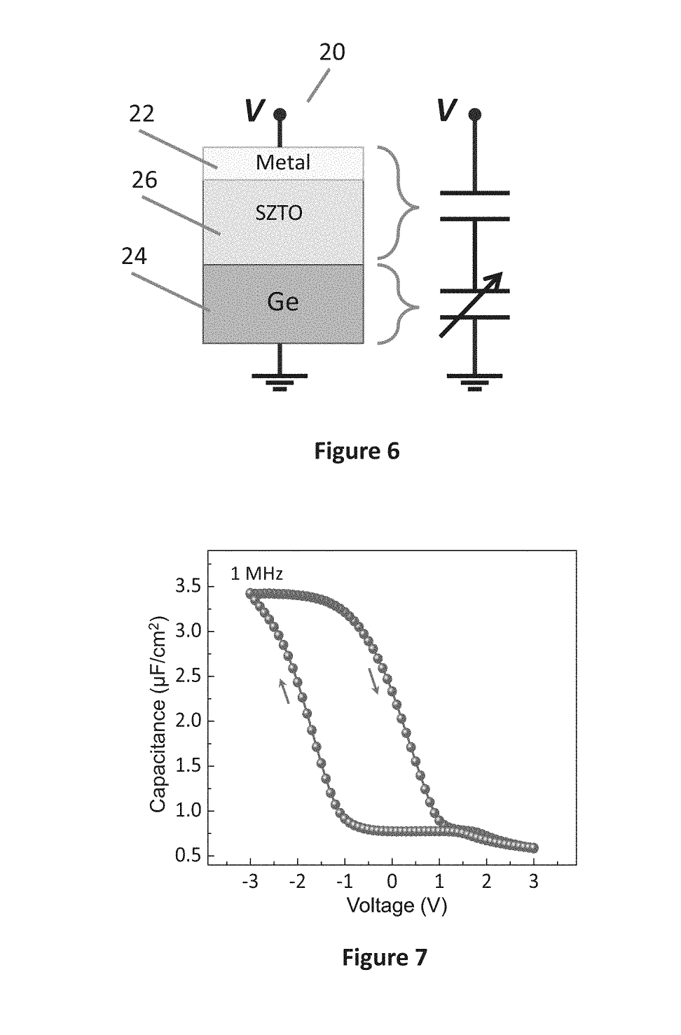

FIG. 6 illustrates a MOS capacitor 20 embodiment of the invention. The capacitor generally comprises two conducting materials with a dielectric in the middle. The illustrated capacitor 20 comprises a metal conductive layer 22 at the top, a bottom electrode 24 (e.g. germanium), and an oxide 26 in the middle. In this case, the oxide 26 consists of the fabricated SZTO material. The right-hand side of FIG. 6 represents the capacitance measured across the capacitor 20 when a voltage V is applied. As shown in the right-hand schematic, the capacitance measurement comprises the fixed capacitance of the SZTO oxide 26 layer, as well as the changing capacitance of the bottom semiconducting electrode 24.

FIG. 7 shows the capacitance-voltage (C-V) curve for the capacitor 20 of FIG. 6. As shown in the C-V plot, a unique feature of the capacitor 20 is the hysteretic effect experienced by the device (when the applied voltage is swept between negative and positive) due to use of the fabricated SZTO material as the oxide 26 layer. The hysteresis displayed by the capacitor 20 is consistent with the characteristics of ferroelectric switching.

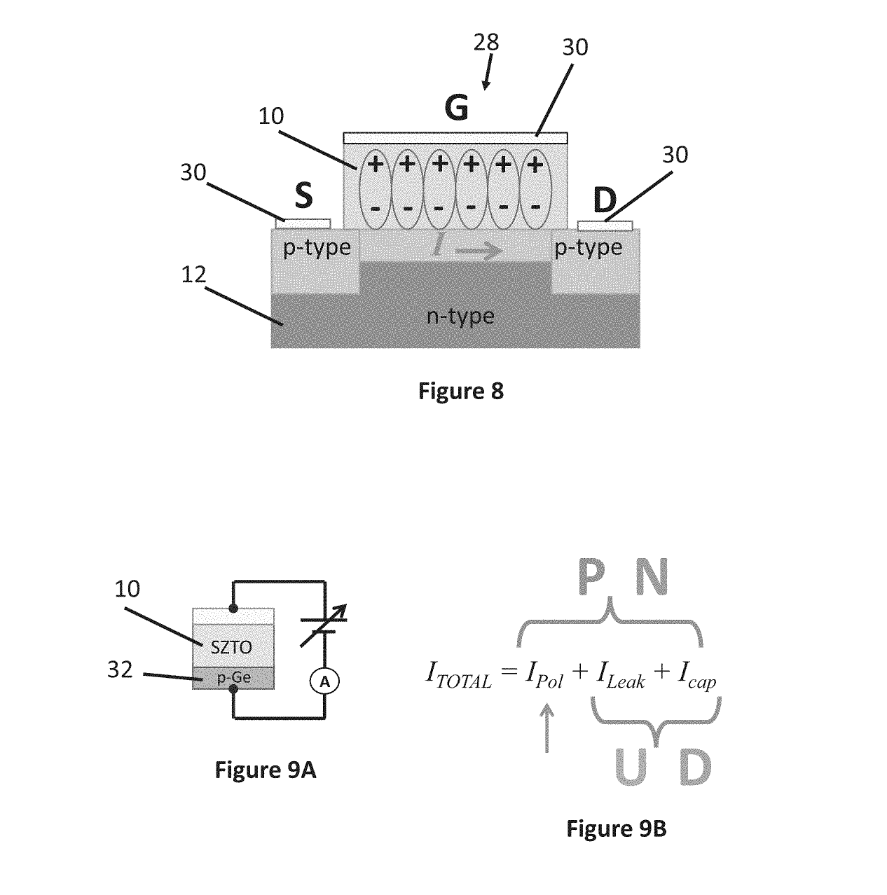

Turning to FIG. 8, an FET 28 embodiment of the invention is illustrated. The SZTO 10 material is deposited onto the substrate 12 as described herein. In some embodiments, the SZTO 10 material is deposited on the substrate 12 without a buffer layer to form the gate. Although the FET 28 is depicted comprising metal electrodes 30 affixed to the SZTO 10 and substrate 12 to respectively implement the gate (G), source (S), and drain (D) contacts, it will be appreciated by those skilled in the art that other embodiments may be implemented in various configurations as known in the art (e.g., without metal electrodes, in various chip structures, etc.).

The polarization of a ferroelectric can be quantified by determining the presence of a plus or minus dipole. If the material is ferroelectric, with plus or minus dipoles throughout the material, the top surface of the material has an excess positive or negative charge. This charge can be quantified in terms of charge per unit area (e.g., micro-coulombs per square centimeter). A “PUND” technique was used to directly measure the polarization at the surface of the fabricated SZTO material. FIG. 9A illustrates how this measurement is carried out.

As illustrated in FIG. 9A, a potential bias is applied across the gate stack of SZTO 10 material and germanium bottom electrode 32. The current through the stack is then measured. In any capacitor, a leakage current is experienced due to imperfections in the dielectric. When the biasing voltage is swept and the coercive voltage is reached, the ferroelectric switches from up to down polarization or vice-versa depending on how the voltage is swept. The switching polarization is manifested as an excess current. FIG. 9B illustrates the total current passing through the stack of FIG. 9A.

In FIG. 9B, I_{TOTAL} represents all the current contributions for the measured current through the stack. I_{POL} is the current due to the switching polarization. I_{LEAK} is the current leakage contribution, and I_{cap} is the capacitive contribution (function of the rate at which the biasing voltage is ramped). The PUND measurement allows one to isolate the polarization current I_{POL} from the leakage current I_{LEAK} and capacitive current I_{cap} contributions. The I_{POL} contribution arises from ferroelectricity, while I_{LEAK} and I_{cap} contributions can arise in any dielectric capacitor, ferroelectric or non-ferroelectric.

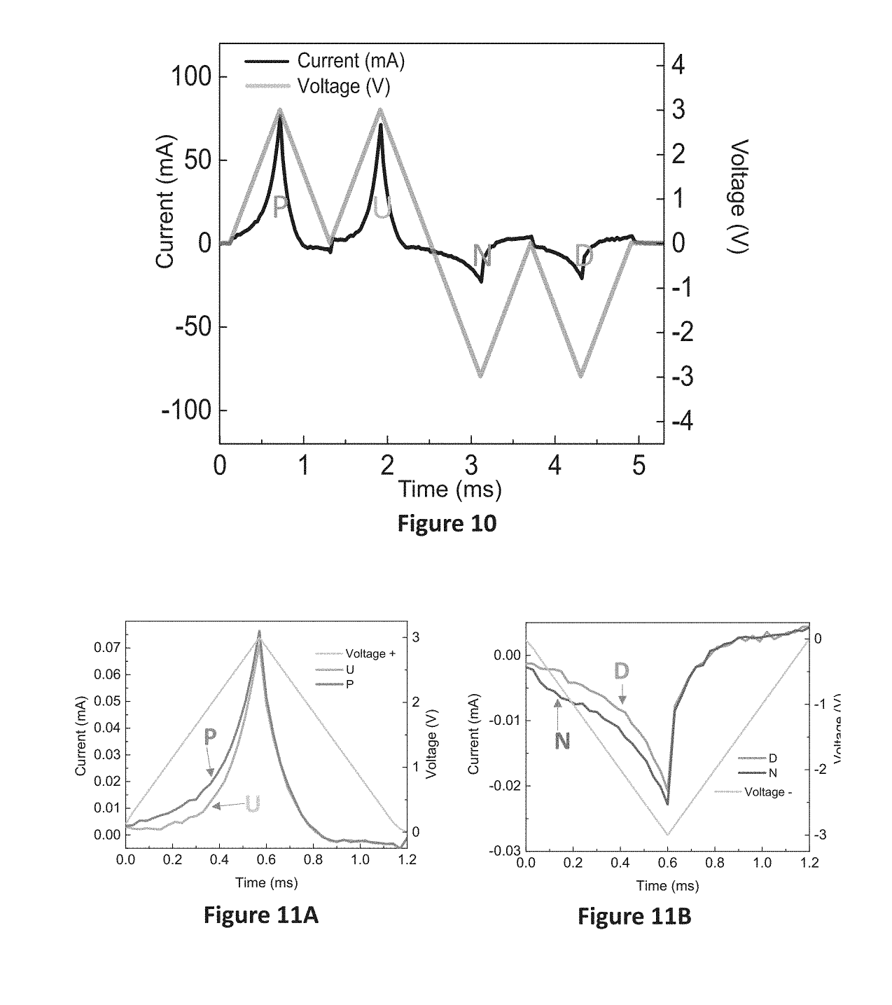

FIG. 10 shows a graph of the double-wave method of the applied PUND sequence. As illustrated, the voltage is plotted in light shading (grey) and the current in bold (darker). Starting from left to right, the first voltage pulse (positive pulse, designated “P”) switches the polarization to the ‘down’ state. This P pulse contains all three current components (i.e. I_{TOTAL}). The next pulse (positive pulse, designated “U”) only measures the leakage current I_{LEAK} and the capacitive current I_{cap} contributions, because the ferroelectric is already in the ‘down’ polarization state. The next voltage pulse (negative pulse, designated “N”) switches the polarization state and measures all three current components (i.e. I_{TOTAL}). The following negative pulse (designated “D”) measures only the leakage current I_{LEAK} and the capacitive current I_{cap} contributions, because again, the pulse did not switch the polarization state. For a ferroelectric material, the current should be greater for the P pulse compared to the U pulse, and greater for the N pulse compared to the D pulse. This is because for the P and N pulses, an excess polarization current I_{POL} should be evident, which combines with the other two current components (i.e., I_{LEAK} and I_{cap}).

Turning to FIGS. 11A and 11B, the current measurements of FIG. 10 are plotted normalized to the same time scale. FIG. 11A shows the P and U pulse measurements overlaid and FIG. 11B shows the N and D pulse measurements overlaid. This plotting clearly shows the excess current (I_{POL}) in the P and N pulses, which is consistent with the switching polarization of the fabricated SZTO ferroelectric material.

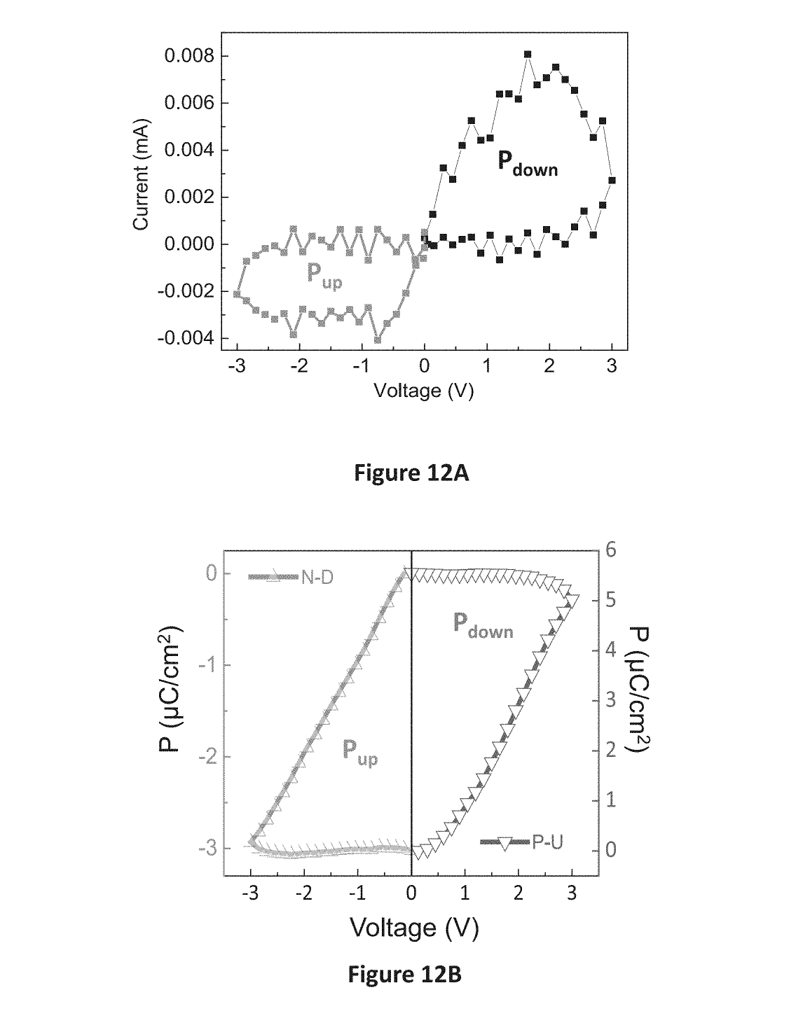

FIG. 12A shows a graph of the switching current for the measurements of FIG. 10. The current is shown plotted as a function of voltage. In this instance, the ‘up’ state polarization (Pᵤₚ) measured a surface charge of approximately 3 micro-coulombs per square centimeter. The ‘down’ state polarization (P_{down}) measured the same approximate surface charge, in the opposite down, polarity. FIG. 12B shows a plot of the polarization versus voltage for the same measurements. By integrating the current with respect to time, the charge is determined (i.e. the polarization). As can be seen in the plot of FIG. 12B, the curve displays a hysteretic component, which is a traditional characteristic of ferroelectric materials.

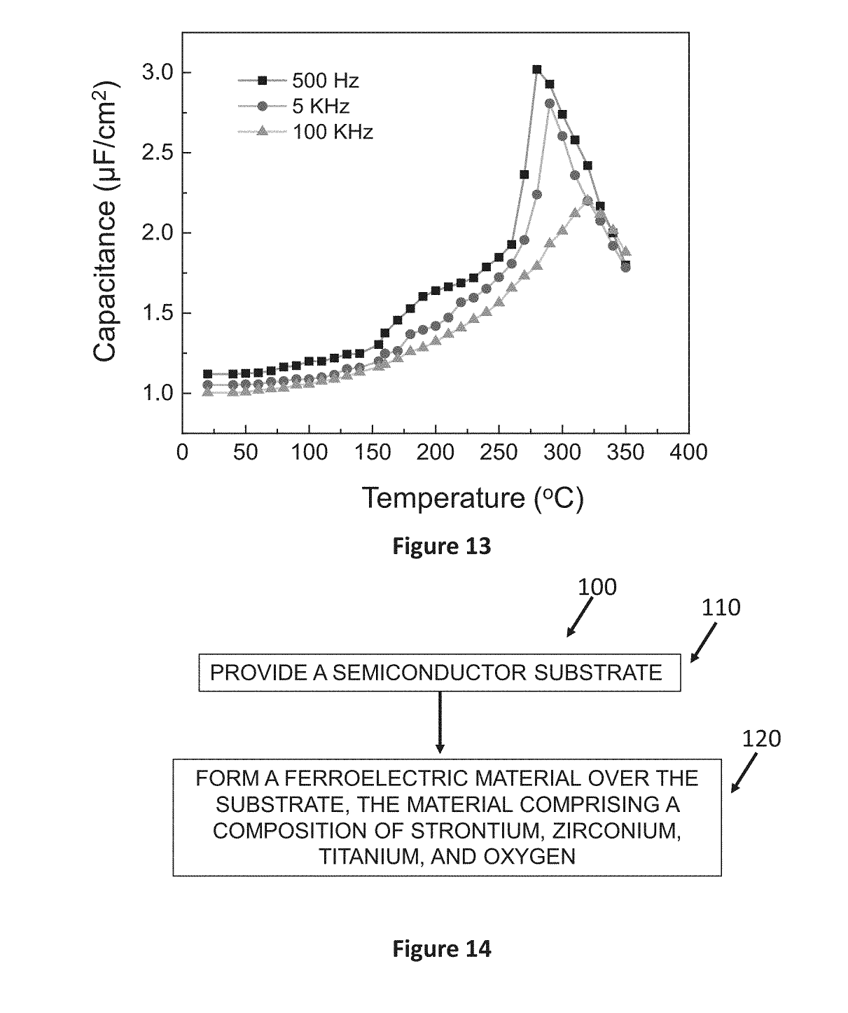

Measuring the capacitance of the material as a function of temperature can reveal insight on the nature of ferroelectricity. FIG. 13 shows a capacitance-temperature plot obtained for a fabricated SZTO ferroelectric embodiment of the invention. As evident in the plot of FIG. 13, a peak or discontinuity is observed at approximately 300 degrees Celsius.

A closer examination of the data in the plot of FIG. 13 reveals certain dispersion in the capacitance peaks measured at various frequencies. For instance, at 500 Hz the capacitance peak occurs slightly below 300 degrees Celsius. However, at 5 KHz the capacitance peak is shifted slightly to the right, and at 100 kHz the peak is shifted even further to the right. The shifting of these peaks as a function of frequency is consistent with a class of ferroelectrics known as “relaxor” ferroelectrics. No additional peak is observed below 300 degrees Celsius, indicating that SZTO is a canonical relaxor.

As previously mentioned, prior studies of bulk SZTO compounds have shown that such compositions do not exhibit ferroelectric properties. As will be appreciated by those skilled in the art, the disclosed fabrication of the ferroelectric SZTO material via thin-film growth may introduce certain non-stoichiometry in the combination of the elements. Stoichiometry is the calculation or measure of the relative quantities or ratios of elements in the compound. A typical balanced reaction results in a composition in its ground or lowest energy state (i.e., stoichiometric). When vacancies or non-stoichiometry is introduced, the energy in the lattice is increased, which is not the natural state for the combined elements. Nonetheless, by controlling the composition of the individual SZTO elements as disclosed herein, the stoichiometry of the material can be directly altered. Although embodiments of the invention were produced using an MBE technique to create the SZTO compositions, fabrication of the ferroelectric SZTO materials is not limited to any one particular deposition or growth technique.

FIG. 14 is a flow chart illustrating, in accordance with some embodiments, a method 100 of the invention, i.e., a method for making a ferroelectric semiconductor device. At a first step 110, a semiconductor substrate is provided. At a second step 120, a ferroelectric material is formed over the substrate, wherein the ferroelectric material comprises a composition of the elements strontium (Sr), zirconium (Zr), titanium (Ti), and oxygen (O).

In light of the principles and example embodiments described and illustrated herein, it will be recognized that the example embodiments can be modified in arrangement and detail without departing from such principles. Also, the foregoing discussion has focused on particular embodiments, but other configurations are also contemplated. For example, embodiments of the invention may be configured to integrate memory and logic in a single device. Even though expressions such as “in one embodiment,” “in another embodiment,” or the like are used herein, these phrases are meant to generally reference embodiment possibilities, and are not intended to limit the invention to particular embodiment configurations. As used herein, these terms may reference the same or different embodiments that are combinable into other embodiments. As a rule, any embodiment referenced herein is freely combinable with any one or more of the other embodiments referenced herein, and any number of features of different embodiments are combinable with one another, unless indicated otherwise.

Similarly, although example methods or processes have been described with regard to particular steps or operations performed in a particular sequence, numerous modifications could be applied to those methods or processes to derive numerous alternative embodiments of the present invention. For example, alternative embodiments may include methods or processes that use fewer than all of the disclosed steps or operations, methods or processes that use additional steps or operations, and methods or processes in which the individual steps or operations disclosed herein are combined, subdivided, rearranged, or otherwise altered.

This disclosure may include descriptions of various benefits and advantages that may be provided by various embodiments. One, some, all, or different benefits or advantages may be provided by different embodiments. Similarly, items such as modules, chips, components, etc., may be implemented as firmware or hardware, or as any combination of firmware and hardware.

In view of the wide variety of useful permutations that may be readily derived from the example embodiments described herein, this detailed description is intended to be illustrative only, and should not be taken as limiting the scope of the invention. What is claimed as the invention, therefore, are all implementations that come within the scope of the following claims, and all equivalents to such implementations.

What is claimed is:

1. A method for making a ferroelectric semiconductor device, comprising:
providing a semiconductor substrate;
forming a ferroelectric material over the substrate; and
wherein the ferroelectric material comprises a composition of the elements strontium (Sr), zirconium (Zr), titanium (Ti), and oxygen (O).

2. The method of claim 1, wherein the composition comprises SrZr_{0.7}Ti_{0.3}O₃.

3. The method of claim 1, wherein forming the ferroelectric material comprises forming a layer of the composition on the substrate using a molecular beam epitaxy technique.

4. The method of claim 1, wherein the substrate comprises p-type germanium (Ge).

5. The method of claim 1, wherein forming the ferroelectric material comprises forming a plurality of monocrystalline thin-film layers of the composition on the substrate.

6. The method of claim 1, wherein forming the ferroelectric material over the substrate comprises forming the material with a uniform thickness in the range of five to fifteen nanometers.

7. The method of claim 1, wherein the ferroelectric semiconductor device is configured as a field-effect transistor.

8. The method of claim 1, wherein the ferroelectric semiconductor device is configured as a memory cell.

9. The method of claim 1, wherein the ferroelectric semiconductor device is configured as a capacitor.

10. The method of claim 1, wherein the ferroelectric material is configured as a relaxor ferroelectric.

11. A ferroelectric semiconductor device, comprising:
a semiconductor substrate;
a ferroelectric material formed over the substrate; and
wherein the ferroelectric material comprises a composition of the elements strontium (Sr), zirconium (Zr), titanium (Ti), and oxygen (O).

12. The semiconductor device of claim 11, wherein the composition comprises SrZr_{0.7}Ti_{0.3}O₃.

13. The semiconductor device of claim 11, wherein the ferroelectric material comprises an epitaxially formed layer of the composition on the substrate.

14. The semiconductor device of claim 11, wherein the substrate comprises p-type germanium (Ge).

15. The semiconductor device of claim 11, wherein the ferroelectric material comprises a plurality of monocrystalline thin-film layers of the composition formed on the substrate.

16. The semiconductor device of claim 11, wherein the ferroelectric material comprises a uniform thickness in the range of five to fifteen nanometers.

17. The semiconductor device of claim 11, wherein the ferroelectric semiconductor device is configured as a field-effect transistor.

18. The semiconductor device of claim 11, wherein the ferroelectric semiconductor device is configured as a memory cell.

19. The semiconductor device of claim 11, wherein the ferroelectric material is configured as a relaxor ferroelectric.

20. The semiconductor device of claim 11, wherein the ferroelectric material is configured as a capacitor.
